(19) United States
(12) Patent Application Publication
(10) Pub. No.: US 2026/0009829 A1
(43) Pub. Date: Jan. 8, 2026

(54) METHOD, DEVICE, APPARATUS, AND STORAGE MEDIUM FOR DETERMINING OVERLOAD BOUNDARY OF MMC

(71) Applicant: Shandong University, Jinan (CN)

(72) Inventors: Zhijie Liu, Jinan (CN); Kejun Li, Jinan (CN); Jinxin Dou, Jinan (CN); Yuanyuan Sun, Jinan (CN); Gang Shen, Jinan (CN); Yuxiang Kuang, Jinan (CN); Xiaohan Huang, Jinan (CN); Canyu Cui, Jinan (CN); Kaiqi Sun, Jinan (CN); Baihe Su, Jinan (CN)

(73) Assignee: Shandong University, Jinan (CN)

(21) Appl. No.: 19/328,220

(22) Filed: Sep. 14, 2025

(30) Foreign Application Priority Data
Dec. 10, 2024 (CN) 202411803379.X

(51) Int. Cl. G01R 25/00

(52) U.S. Cl. CPC G01R 25/00

(57) ABSTRACT

The invention provides a method, device, apparatus, and storage medium for determining the overload boundary of MMC, which belongs to the field of DC transmission technology. The overload operation boundary of the MMC may be accurately determined, which is helpful to set the load level of the MMC reasonably in the design and operation process to ensure safe and efficient operation.

### TECHNICAL FIELD

The present disclosure belongs to the field of DC transmission technology, and specifically, a method, device, apparatus, and storage medium for determining the overload boundary of MMC.

### BACKGROUND

Modular Multilevel Converter (MMC) refers to a new power electronic converter with characteristics of high voltage utilization, good control performance, high operation efficiency, good scalability, and redundancy. It is widely used in high voltage direct current transmission (HVDC) and renewable energy access. In addition to the flexibility of MMC, the grid-structured MMC has the characteristics of a grid-structured converter, which can provide inertial support for the system and improve the stability and reliability of the power system. It is an important part of promoting the construction process of a new power system with a high proportion of new energy. In the face of sudden load demand and power fluctuation, if the apparatus cannot withstand the overload demand, the power supply will be interrupted, and the apparatus will be damaged, which will affect the stable operation of the whole power grid. Therefore, the grid-structured MMC needs to have a certain overload operation capability.

The clear structure of the overload operation boundary is very important for the stable operation of the converter, because it is not only the trigger condition for the subsequent overload operation control, but also the basic guarantee to prevent the MMC from exceeding the operating limit. Under the background of an increasingly complex power system and changing load demand, establishing a clear overload boundary can not only improve the reliability of MMC, but also enhance the system's ability to cope with various power shocks. It is of great practical significance to construct the overload operation boundary of grid-structured MMC for improving the overall security and stability of the power system.

In the existing technology, the determination of the overload boundary of MMC is mainly based on the historical operation data of MMC, which leads to unclear and inaccurate operation data of the overload boundary of MMC.

### SUMMARY

In order to solve the problem that the overload boundary of MMC is not clear, the present disclosure provides a method, device, apparatus, and storage medium for determining an overload boundary of MMC.

In order to achieve the above purpose, the present disclosure provides the following technical scheme:
Firstly, a method for determining an overload boundary of MMC is provided, including:
obtaining a power factor angle of a target MMC, and setting constraint ranges of an amplitude and a phase angle of a zero-sequence signal;
initializing two different working conditions of the target MMC, determining a maximum modulation signal margin of the two different working conditions under a condition of zero-sequence signal injection by the power factor angle, an apparent power corresponding to the two working conditions and a constraint range of the amplitude and phase angle of the zero-sequence signal; the two different working conditions are the working condition corresponding to a first apparent power and the working condition corresponding to a second apparent power;
based on the two different working conditions and the corresponding maximum modulation signal margin under the condition of zero-sequence signal injection, obtaining a third apparent power by a secant iteration method; and when the modulation signal margin corresponding to the third apparent power is within a preset error range, determining the third apparent power as a maximum operating power of the target MMC at a current power factor angle;
by adjusting the power factor angle, obtaining a maximum operating power curve of the target MMC under different power factor angles, that is, a limit boundary of an overload operation of the target MMC.

In some embodiments, the method also includes:
after initializing the two different working conditions of the target MMC, determining the maximum modulation signal margin of the two different working conditions without a zero-sequence signal by the power factor angle and the apparent power corresponding to the two working conditions;
based on the maximum modulation signal margin of the two different working conditions and their corresponding zero-sequence signal-free conditions, obtaining a fourth apparent power by an iteration of the secant method; and when the modulation signal margin corresponding to the fourth apparent power is within the preset error range, determining the fourth apparent power as a starting operating power of the target MMC at the current power factor angle;
by adjusting the power factor angle, the starting power curve of the target MMC under different power factor angles is obtained, that is, a starting boundary of the overload operation of the target MMC.

In some embodiments, determining a maximum modulation signal margin of the two different working conditions under a condition of zero-sequence signal injection by the power factor angle, an apparent power corresponding to the two working conditions, and a constraint range of the amplitude and phase angle of the zero-sequence signal, including:
constructing a correlation between the amplitude and phase angle of the power factor angle, apparent power, and zero-sequence signal in the target MMC and the modulation signal margin;
by adjusting the amplitude and phase angle of the zero-sequence signal within the constraint range, the zero-sequence signal that maximizes the modulation signal margin is determined to be an optimal zero-sequence signal;
according to the initialized first apparent power and the second apparent power, obtaining the maximum modulation signal margin at the current power factor angle by the optimal zero-sequence signal.

In some embodiments, the iterative formula of the secant method is:

$${S}_{n + 2} = {S}_{n + 1} - \frac{{M}_{gin} ( {S}_{n + 1} )}{{M}_{gin} ( {S}_{n + 1} ) - {M}_{gin} ( {S}_{n} )} ( {S}_{n + 1} - {S}_{n} ) ;$$

where Sₙ₊₂ is the third apparent power or the fourth apparent power, Sₙ and Sₙ₊₁ are the first apparent power and the second apparent power, respectively; M_{gin}(Sₙ) and M_{gin}(Sₙ₊₁) are the maximum modulation signal margins corresponding to the first apparent power and the second apparent power, respectively.

In some embodiments, the method also includes:
under the condition that the modulation signal margin corresponding to the third apparent power or the fourth apparent power is not in the preset range, iterating the first apparent power and the second apparent power of the target MMC by the secant method until the modulation signal margin is within the preset error range.

In some embodiments, the constraint range expression of the amplitude and phase angle of the zero-sequence signal is:

$$\{ \begin{matrix}0 \leq {A}_{3} \leq 0.5 \\ 0 \leq {α}_{3} \leq 2 π\end{matrix} ;$$

a definition of the modulation signal margin M_{gin} of the target MMC is:

$${M}_{gin} = \frac{1 - {m}_{rect}}{2} ;$$

where A₃ is an amplitude of the zero-sequence signal, α₃ is a phase angle corresponding to A₃, m_{rect} is a correction value of the modulation signal, which is obtained by the power factor angle and the apparent power.

Secondly, a device for determining the overload boundary of MMC is provided. The device includes:
an acquisition module, configured to obtain the power factor angle of the target MMC, and the constraint ranges of the zero-sequence signal amplitude and phase angle are set based on a physical limitation of the target MMC.
a calculation module, configured to initialize two different working conditions of the target MMC, the maximum modulation signal margin of the two different working conditions under the condition of zero-sequence signal injection is determined by the power factor angle, the apparent power corresponding to the two working conditions and the constraint range of the amplitude and phase angle of the zero-sequence signal; the two different working conditions are the working condition corresponding to the first apparent power and the working condition corresponding to the second apparent power;
an iterative module, configured to obtain the third apparent power based on the two different working conditions and the corresponding maximum modulation signal margin in the case of zero-sequence signal injection. When the modulation signal margin corresponding to the third apparent power is within the preset error range, the third apparent power is determined as the maximum apparent power of the target MMC to inject the optimal zero-sequence signal at the current power factor angle;
a determination module, configured to adjust the power factor angle, and the maximum apparent power curve of the optimal zero-sequence signal injected into the target MMC at different power factor angles is obtained, which is the limit boundary of the overload operation of the target MMC.

In addition, a computer-readable storage medium is also provided, the storage medium stores a computer program; when the computer program is executed by the processor, the above method of determining the overload boundary of MMC is realized.

Finally, a computer apparatus is provided, including a memory, a processor, and a computer program stored on the memory and running on the processor, the processor implements the above method to determine the MMC overload boundary when executing the program.

The method for determining the overload boundary of MMC provided by the present disclosure has the following beneficial effects:

Firstly, the two apparent powers of the target MMC are initialized, and the maximum modulation signal margin of the initial apparent power is determined. Secondly, the first apparent power and the second apparent power of the target MMC are iterated by the secant method to obtain the third apparent power. In this way, the operating power of the target MMC is fitted by iterating the apparent power of the target MMC, and the corresponding zero-sequence signal is injected in the iterative process to find the maximum value of the modulation signal margin, and then the third apparent power is obtained. In this way, the third apparent power is obtained by maximizing the modulation signal margin to fit the operating power of the MMC. It may be determined as the maximum value of MMC in the power range of stable operation. In this way, the overload operation boundary of grid-structured MMC may be clearly constructed, the overload capacity of MMC may be accurately defined, and the response ability of the power system to sudden faults may be enhanced. It is helpful to reasonably set the load level of MMC in the design and operation process, ensure its operation under safe and efficient conditions, and enhance the response ability of the power system to sudden faults. When the power grid fails or the demand changes sharply, the operation state of MMC may be quickly adjusted according to the overload operation boundary, so as to adapt to the new operating conditions, avoid apparatus damage or system failure caused by overload, and ensure the safe and stable operation of the power system. Improve the reliability and stability of the system.

### BRIEF DESCRIPTION OF THE DRAWINGS

In order to more clearly explain the embodiment of the present disclosure and its design scheme, the following will briefly introduce the attached drawings required for the embodiment. The drawings in the following description are only part of the implementation examples of the present disclosure. For ordinary technicians in this field, other drawings may be obtained according to these drawings without paying for creative labor.

FIG. 1 is a flow diagram of the method for determining the overload boundary of MMC provided by the present disclosure according to an example.

FIG. 2 is a flow diagram of the steps of the method for determining the maximum operating power of MMC overload operation provided by the present disclosure according to an example.

FIG. 3 is a flow diagram of the steps of the method for determining the initial operating power of MMC overload operation provided by the present disclosure according to an example.

FIG. 4 shows a modulation signal waveform and margin data diagram for determining MMC overload operation provided by the present disclosure according to an example.

FIG. 5 provides a device block diagram for determining the overload boundary of the MMC provided by the present disclosure according to an example.

### DETAILED DESCRIPTION OF THE EMBODIMENTS

In order to enable the technical personnel in this field to better understand the technical scheme of the present disclosure and implement it, the following is a detailed description of the present disclosure in combination with the attached drawings and specific implementation examples. The following embodiments are only used to more clearly explain the technical scheme of the present disclosure, and cannot be used to limit the scope of protection of the present disclosure.

The present disclosure relates to a construction method for the overload operation boundary of grid-structured MMC. According to the given power factor angle φ and apparent power S of MMC, the maximum modulation signal margin Mgin, zero-sequence signal amplitude OptA3, and phase angle Optα3 under the condition of zero-sequence signal injection may be calculated. By iteratively calculating the apparent power until the modulation signal margin Mgin is greater than 0 and less than or equal to the allowable error tol, the overload limit power under the power factor angle may be obtained. By changing the power factor angle, the overload operation limit power under each power factor angle may be obtained. The limit boundary curve and function of MMC overload operation are obtained by nonlinear least square fitting.

Similarly, according to the given power factor angle φ of MMC, the amplitude of zero-sequence signal is set to 0, and the apparent power is calculated iteratively until the modulation signal margin Mgin is greater than 0 and less than or equal to the allowable error tol, and the initial power of overload operation under this power factor angle may be obtained. By changing the power factor angle, the overload starting power under each power factor angle may be obtained. The initial boundary curve and function of the MMC overload operation are obtained by nonlinear least squares fitting.

Combined with the attached figures, the technical schemes provided by each embodiment of the present disclosure are described in detail.

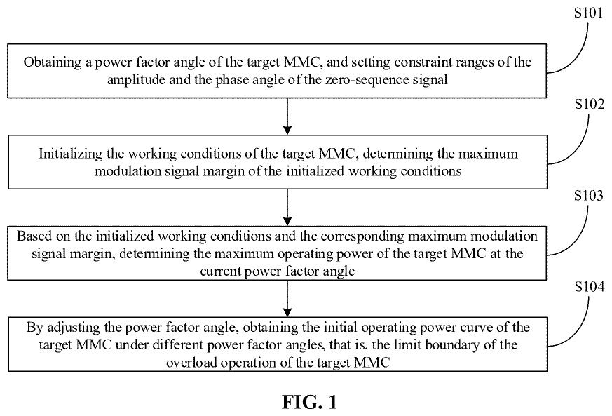

Firstly, the present disclosure provides a method for determining the overload boundary of MMC, as shown in FIG. 1, including the following steps:

S101, the power factor angle of the target MMC is obtained, and the constraint ranges of the zero-sequence signal amplitude and phase angle are set.

The power factor angle refers to the phase difference between the voltage and the current. This parameter is of great significance in evaluating the power transmission efficiency and operational stability of MMC. In practical applications, a dedicated power factor meter or phase meter may be used to directly measure the power factor angle of MMC.

Based on the physical limitation of the target MMC, the constraint range of the amplitude and phase angle of the zero-sequence signal is set as follows:

$$\{ \begin{matrix}0 \leq {A}_{3} \leq 0.5 \\ 0 \leq {α}_{3} \leq 2 π\end{matrix} ;$$

S102, the target MMC condition is initialized, and the maximum modulation signal margin of the initialization condition is determined.

The two different working conditions of the target MMC are initialized, and the maximum modulation signal margin of the two different working conditions is determined in the case of zero-sequence signal injection through the power factor angle, the apparent power corresponding to the two working conditions, and the constraint ranges of the zero-sequence signal amplitude and phase angle. The two different working conditions are the working condition corresponding to the first apparent power and the working condition corresponding to the second apparent power.

Specifically, the correlation between the amplitude and phase angles of the power factor angle, apparent power, and zero-sequence signal in the target MMC and the modulation signal margin is constructed. By adjusting the amplitude and phase angle of the zero-sequence signal within the constraint range, the zero-sequence signal that maximizes the modulation signal margin is determined to be the optimal zero-sequence signal. According to the initialized first apparent power and second apparent power, the maximum modulation signal margin under the current power factor angle is obtained by the optimal zero-sequence signal.

The power factor angle φi is input, and the initial value of the number of iterations n is set to 0. According to the secant method, the given apparent power Sₙ and Sₙ₊₁ are the initial values of the iteration, that is, S₀ and S₁. The initial value of the iteration does not affect the final convergence result of the secant method, and its value only affects the number of iterations and the calculation time. S0=800e6 MW, S1=1500e6 MW may be set.

The optimal zero-sequence signals OptA₃, α₃|(Sₙ, φᵢ) and Opt_{A3, . . . ,α3}|(Sₙ₊₁, φᵢ) under two working conditions Sₙ&φᵢ and Sₙ₊₁&φᵢ are calculated. The definition of the optimal zero-sequence signal is to inject the amplitude and angle of the zero-sequence signal under certain operating conditions. When the MMC modulation signal margin M_{gin} is maximum, the zero-sequence signal is determined to be the optimal zero-sequence signal.

The definition of the MMC modulation signal margin M_{gin} is as follows:

$${M}_{gin} = \frac{1 - {m}_{rect}}{2} ;$$

where m_{rect} is the correction value of the modulation signal, and its expression is as follows:

$${m}_{rect} = max \{ \vert 2 {S}_{m , ap} ( t ) - 1 \vert \} ;$$

where S_{m.αp}(t) is the A-phase upper bridge arm modulation signal of MMC, which is generated by MMC station-level control: power controller, circulating current controller, average capacitor voltage controller, and zero-sequence signal injection controller.

Taking the bridge arm modulation signal on phase A as an example, its expression is as follows

$${S}_{ap} ( t ) = {A}_{0} - {A}_{1} cos ( ω t + {α}_{1} ) - {A}_{2} cos ( 2 ω t + {α}_{2} ) - {A}_{3} cos ( 3 ω t + {α}_{3} ) ;$$

where A₀, A₁, A₂ and A₃ are the amplitudes of DC, the first, second and third harmonic components, respectively, and 3^{rd} harmonic component is the zero-sequence signal; α₁, α₂ and α₃ denotes the corresponding phase angles; ω is the frequency of the fundamental frequency angle, and the amplitude A₃ of the third harmonic component and its corresponding phase angle α₃ constitute the zero-sequence signal.

In this present disclosure, the power factor angle φ, the apparent power S and the zero-sequence signal injection controller input A₃ and α₃ in the MMC station-level control are regarded as variables, and the remaining parameters are regarded as constants. Therefore, the modulation signal margin M_{gin} may be regarded as a function of φ, S, A₃, and α₃, as follows:

$${M}_{gin} = f ( φ , S , {A}_{3} , {α}_{3} ) .$$

S103, based on the initialization condition and its corresponding maximum modulation signal margin, the maximum operating power of the target MMC under the current power factor angle is determined.

Based on the two different working conditions and the corresponding maximum modulation signal margin in the case of zero-sequence signal injection, the third apparent power is obtained by chord truncation iteration. When the modulation signal margin corresponding to the third apparent power is within the preset error range, the third apparent power is determined to be the maximum operating power of the target MMC at the current power factor angle, that is, the limit power of the overload operation of the target MMC.

Based on the optimal zero-sequence signal obtained in the above steps, the modulation signal margin M_{gin}(Sₙ) and M_{gin}(Sₙ₊₁) of the corresponding optimal zero-sequence signals OptA₃, α₃|(Sₙ, φᵢ) and OptA₃, α₃|(Sₙ₊₁, φᵢ) injected under two working conditions Sₙ&φᵢ, Sₙ₊₁&φᵢ are calculated.

Specifically, the maximum operating power of the target MMC may be determined by the following formula:

$${S}_{n + 2} = {S}_{n + 1} - \frac{{M}_{gin} ( {S}_{n + 1} )}{{M}_{gin} ( {S}_{n + 1} ) - {M}_{gin} ( {S}_{n} )} ( {S}_{n + 1} - {S}_{n} ) .$$

In the case of determining the maximum operating power, M_{gin}(Sₙ) and M_{gin}(Sₙ₊₁) in the above formula are the first apparent power modulation signal margin and the second apparent power modulation signal margin corresponding to the optimal zero-sequence signal, respectively.

Whether the modulation signal margin under Sₙ₊₂&φᵢ condition is within the preset error range is calculated and judged, that is, greater than 0 and less than or equal to the allowable error tol, as follows:

$$0 < {M}_{gin} ( {S}_{n + 2} ) \leq tol ;$$

if the modulation signal margin is greater than 0 and less than or equal to the allowable error tol, the iteration ends.

When the modulation signal margin corresponding to the third apparent power or the fourth apparent power is outside the preset range, the first apparent power and the second apparent power of the target MMC are iterated by the secant method until the modulation signal margin is within the preset error range.

At the end of the iteration, the Sₙ₊₂ is output as the maximum operating power, and then the overload operation boundary of the target MMC under the power factor angle φᵢ is determined.

S104, by adjusting the power factor angle, the starting power curve of the target MMC under different power factor angles is obtained, which is the starting boundary of the overload operation of the target MMC.

Because the maximum operating power corresponding to different power factor angles is different, the power factor angle may be adjusted to obtain the curve of the maximum operating power corresponding to multiple power factor angles, which is the limit boundary of the overload operation of the target MMC.

In addition, after determining the limit boundary of the overload operation of the target MMC, it is also necessary to determine the starting boundary of the overload operation.

Specifically, after initializing two different operating conditions of the target MMC, the maximum modulation signal margin of the two different operating conditions without a zero-sequence signal is determined by the power factor angle and the apparent power corresponding to the two operating conditions. Based on the two different working conditions and the corresponding maximum modulation signal margin without zero-sequence signal, the fourth apparent power is obtained by an iteration of the secant method. When the modulation signal margin corresponding to the fourth apparent power is within the preset error range, the fourth apparent power is determined as the starting operating power of the target MMC under the current power factor angle. By adjusting the power factor angle, the starting power curve of the target MMC under different power factor angles is obtained, which is the starting boundary of the overload operation of the target MMC.

The difference between the process of determining the initial boundary of the overload operation and the determination of the limit boundary of the overload operation is that the zero-sequence signal is not injected when the maximum modulation signal margin corresponding to the working condition is determined.

The formula for determining the initial operating power of the target MMC overload operation is

$${S}_{n + 2} = {S}_{n + 1} - \frac{{M}_{gin} ( {S}_{n + 1} )}{{M}_{gin} ( {S}_{n + 1} ) - {M}_{gin} ( {S}_{n} )} ( {S}_{n + 1} - {S}_{n} ) .$$

When the initial operating power is determined, M_{gin}(Sₙ) and M_{gin}(Sₙ₊₁) in the above formula are the maximum modulation signal margin corresponding to the first apparent power and the maximum modulation signal margin corresponding to the second apparent power without zero-sequence signal injection, respectively.

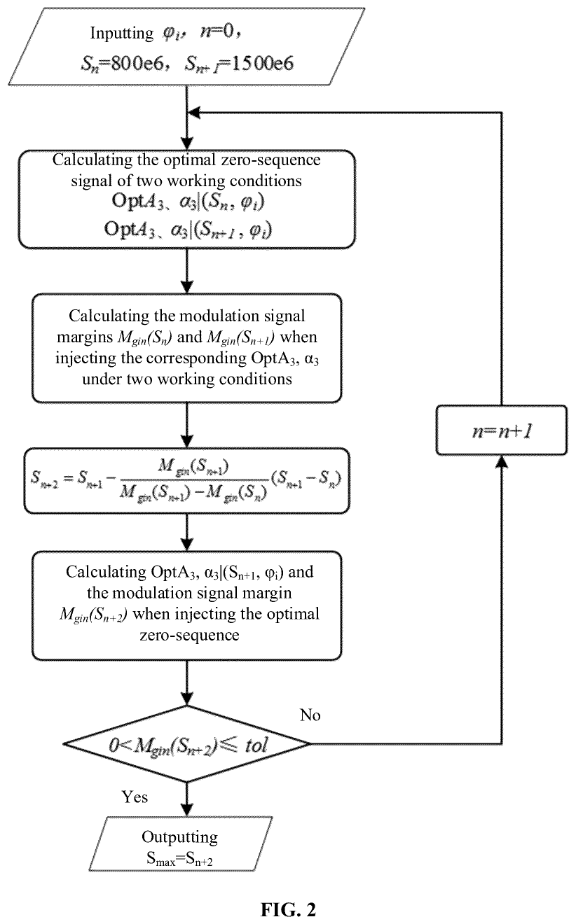

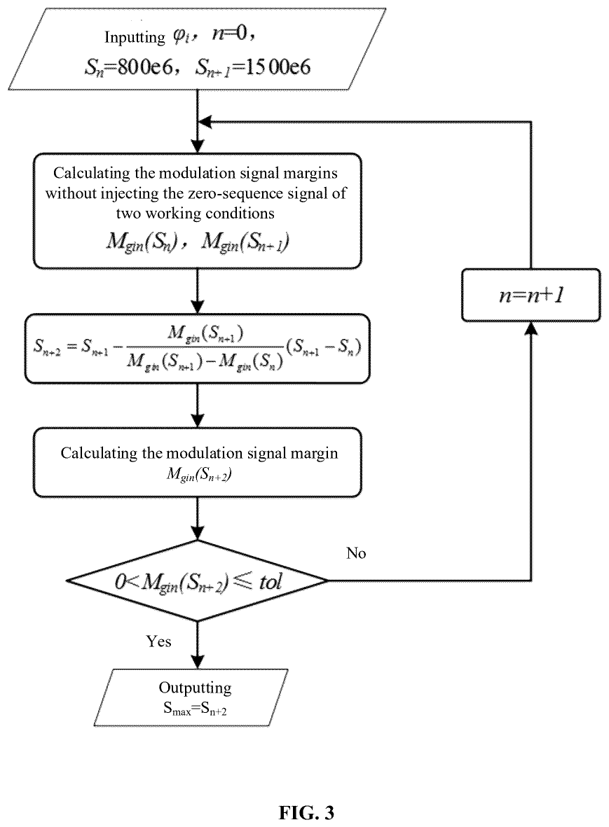

At the end of the iteration, the maximum operating power or the initial operating power is output, and then the two overload operating boundaries of the target MMC under the power factor angle φᵢ are determined. The steps of the method flow to determine the maximum operating power and initial operating power of the target MMC overload operation are shown in FIG. 2 and FIG. 3, respectively.

The nonlinear least squares method is used to fit the different overload operation boundaries of the target MMC, and the overload operation boundary curve and function of the target MMC are obtained.

For example, the data processing of the obtained MMC operation area is carried out, and the elliptic function equation shown below is selected. The specific boundary fitting function model is obtained by nonlinear least squares fitting:

$$f = {( \frac{( x - {x}_{c} )}{a} )}^{2} + {( \frac{( y - {y}_{c} )}{b} )}^{2} - 1 ;$$

where (xc, yc) is the center of the ellipse, a is the long semi-axis of the ellipse, and b is the short semi-axis of the ellipse.

Using the above method, firstly, the two apparent powers of the target MMC are initialized, and the maximum modulation signal margin of the initial apparent power is determined. Secondly, the first apparent power and the second apparent power of the target MMC are iterated by the secant method to obtain the third apparent power. In this way, the operating power of the target MMC is fitted by iterating the apparent power of the target MMC, and the corresponding zero-sequence signal is injected in the iterative process to find the maximum value of the modulation signal margin, and then the third apparent power is obtained. In this way, the third apparent power is obtained by maximizing the modulation signal margin to fit the operating power of the MMC. It may be determined as the maximum value of MMC in the power range of stable operation. In this way, the overload operation boundary of grid-structured MMC may be clearly constructed, the overload capacity of MMC may be accurately defined, and the response ability of the power system to sudden faults may be enhanced. It is helpful to set the load level of MMC reasonably in the design and operation process, ensure its operation under safe and efficient conditions, and enhance the response ability of the power system to sudden faults. When the power grid fails or the demand changes sharply, the operation state of MMC may be quickly adjusted according to the overload operation boundary, so as to adapt to the new operating conditions, avoid apparatus damage or system failure caused by overload, ensure the safe and stable operation of power system, and improve the reliability and stability of the system.

In order to verify the method for determining the overload boundary of MMC proposed by the present disclosure, the following is combined with the example. The main circuit parameters of the MMC in the example are shown in Table 1.

TABLE 1
Main circuit parameters of MMC

| Parameter | Value | |
|---|---|---|
| Fundamental wave frequency f | 50 | Hz |
| Rated capacity S_{rated} | 1500 | MW |
| DC-side voltage U_{dc} | ±500 | kV |
| Number of bridge arm sub-modules | 218 | |
| Inductance of bridge arm Lₘ | 75 | mH |
| AC-side inductance Lₜ | 25.4 | mH |
| Capacitance C_{SM} | 15000 | uF |

In order to obtain a complete grid-structured MMC overload operation boundary, the input power factor angle φ₀=0, the iterative calculation error tol=0.01, and the iterative initial value S₀=800 MW, S₁=1500 MW. The calculated OptA₃|(S₀, φ₀)=0.0718, Optα₃|(S₀, φ₀)=3.7429, M_{gin}(S₀)=0.1148; optA₃|(S₁, φ₀)=0.0730, Optα₃|(S₁, φ₀)=4.3388, Mgin(S₁)=0.0938. S₂=4626.7MW is obtained by iterative calculation of the following formula:

$${S}_{n + 2} = {S}_{n + 1} - \frac{{M}_{gin} ( {S}_{n + 1} )}{{M}_{gin} ( {S}_{n + 1} ) - {M}_{gin} ( {S}_{n} )} ( {S}_{n + 1} - {S}_{n} ) ;$$

OptA₃|(S₂, φ₀)=0.1578, Optα₃|(S₂, φ₀)=6.0034, M_{gin}(S₂)=−0.1345; M_{gin}(S₂) is less than 0, which does not satisfy the judgment formula 0<M_{gin}(Sₙ₊₂)≤tol.

Therefore, the iterative calculation is carried out by the formula

$${S}_{n + 2} = {S}_{n + 1} - \frac{{M}_{gin} ( {S}_{n + 1} )}{{M}_{gin} ( {S}_{n + 1} ) - {M}_{gin} ( {S}_{n} )} ( {S}_{n + 1} - {S}_{n} ) ,$$

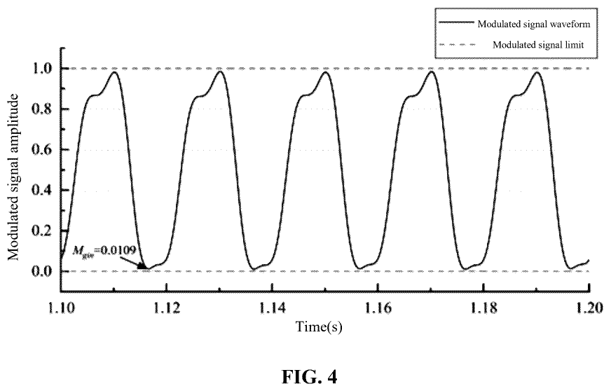

and S₃=2784.6 MW, OptA₃|(S₃, φ₀)=0.1066, Optα₃|(S₃, φ₀)=5.2581, M_{gin}(S₃)=0.0302; M_{gin}(S₃) is greater than the allowable error tol, which does not satisfy the judgment formula 0<M_{gin}(Sₙ₊₂)≤tol, and the iterative calculation is continued until the modulation signal margin satisfies the formula 0<M_{gin}(Sₙ₊₂)≤tol. Through the modeling program of the above steps, when S_{max, φ0}=3059 MW, OptA₃=0.1133, Optα₃=5.4004, the modulation signal margin M_{gin}=0.010; the modulation signal margin obtained under this condition and zero-sequence signal injection satisfies the iteration end condition. When the power factor angle φ₀=0, the overload limit power of MMC injected with a zero-sequence signal is obtained, that is, S_{max, φ0}=3059 MW. The modulation signal waveform and margin under the power factor angle and overload operation limit power are obtained by simulation, as shown in FIG. 4. The simulation results from FIG. 4 show that the modulation signal margin M_{gin}=0.0109 during the waveform display period, and the error is very small compared with the program calculation results, which proves the accuracy of the program calculation results.

Similarly, the iterative power factor angle φ₁=π/24, the above steps are repeated to obtain S_{max,φ1}=2638 MW; keep iterating until the power factor angle φᵢ=2π, and obtain the overload operation limit power of the zero-sequence signal injected at each power factor angle under φᵢ∈[0,2π], that is, the limit boundary of the overload operation of the grid-structured MMC.

The amplitude and phase angle of the zero-sequence signal are set to 0, and the above steps are repeated to obtain an overload operation boundary of MMC without a zero-sequence signal, that is, the starting boundary of the overload operation of the grid-structured MMC. The MMC overload operation boundary data at each power factor angle are shown in Table 2.

TABLE 2
Overload operation boundary of grid-structured MMC

| Power factor | Starting boundary of the | Limit boundary of the |
|---|---|---|
| angle φᵢ | overload operation (MW) | overload operation (MW) |
| 0 | 3059 | 1902 |
| π/24 | 2638 | 1522 |
| π/12 | 2286 | 1232 |
| 2*π/12 | 1778 | 870 |
| 3*π/12 | 1456 | 682 |
| 4*π/12 | 1280 | 578 |
| 5*π/12 | 1183 | 525 |
| 6*π/12 | 1153 | 511 |
| 7*π/12 | 1190 | 525 |
| 8*π/12 | 1280 | 578 |
| 9*π/12 | 1465 | 679 |
| 10*π/12 | 1778 | 868 |
| 11*π/12 | 2287 | 1232 |
| 12*π/12 | 3060 | 1903 |
| 13*π/12 | 4097 | 2959 |
| 14*π/12 | 5281 | 4265 |
| 15*π/12 | 6422 | 5601 |
| 16*π/12 | 7359 | 6753 |
| 17*π/12 | 7980 | 7535 |
| 18*π/12 | 8190 | 7811 |
| 19*π/12 | 7978 | 7534 |
| 20*π/12 | 7363 | 6753 |
| 21*π/12 | 6427 | 5600 |
| 22*π/12 | 5278 | 4265 |
| 23*π/12 | 4091 | 2958 |
| 24*π/12 | 3058 | 1905 |

According to the calculated data, the data scatter diagram of the running domain is drawn, the nonlinear implicit function elliptic curve is selected, and the nonlinear least square method is used for fitting. The overload operation area and the corresponding boundary fitting function of the two grid-structured MMCs are shown in FIG. 4. Among them, the initial boundary fitting curve of overload operation is

$${f}_{start} = {( \frac{( x + 6.35 {e}^{5} )}{3.94 {e}^{9}} )}^{2} + {( \frac{( x + 3.52 {e}^{9} )}{4.03 {e}^{9}} )}^{2} - 1 ,$$

the limit boundary fitting curve of overload operation is

$${f}_{end} = {( \frac{( x + 6883 )}{4.65 {e}^{9}} )}^{2} + {( \frac{( x + 3.52 {e}^{9} )}{4.65 {e}^{9}} )}^{2} - 1.$$

The corresponding residual sum of squares RSS of the fitting function is 1.80e⁻³¹ and 5.34e⁻²⁸ respectively, which is infinitely close to 0. It is proven that the deviation between the fitting function and the actual data is very small, which can well describe the trend and distribution of the data.

Therefore, based on the main circuit parameters of MMC, the starting boundary of the overload operation and the limit boundary of the overload operation of MMC are obtained, and the overload operation boundary of the grid-structured MMC is constructed. The fitting functions of the overload operation boundary are given by the least squares method.

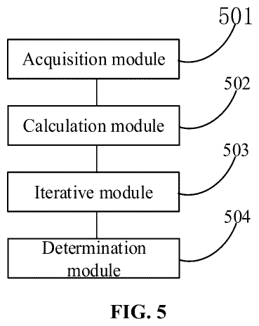

Secondly, the present disclosure also provides a device for determining the overload boundary of MMC, as shown in FIG. 5, including:

The acquisition module 501, configured to obtain the power factor angle of the target MMC, and the constraint ranges of the zero-sequence signal amplitude and phase angle are set based on the physical limitations of the target MMC.

The calculation module 502, configured to initialize two different working conditions of the target MMC, the maximum modulation signal margin of the two different working conditions under the condition of zero-sequence signal injection is determined by the power factor angle, the apparent power corresponding to the two working conditions and the constraint range of the amplitude and phase angle of the zero-sequence signal; the two different working conditions are the working condition corresponding to the first apparent power and the working condition corresponding to the second apparent power.

The iterative module 503, configured to obtain the third apparent power based on the two different working conditions and the corresponding maximum modulation signal margin in the case of zero-sequence signal injection. When the modulation signal margin corresponding to the third apparent power is within the preset error range, the third apparent power is determined as the maximum apparent power of the target MMC to inject the optimal zero-sequence signal at the current power factor angle.

The determination module 504, configured to adjust the power factor angle, and the maximum apparent power curve of the optimal zero-sequence signal injected into the target MMC at different power factor angles is obtained, which is the limit boundary of the overload operation of the target MMC.

The above device is adopted, the two apparent powers of the target MMC are initialized first, and the maximum modulation signal margin of the initial apparent power is determined. Secondly, the first apparent power and the second apparent power of the target MMC are iterated by the secant method to obtain the third apparent power. In this way, the operating power of the target MMC is fitted by iterating the apparent power of the target MMC, and the corresponding zero-sequence signal is injected in the iterative process to find the maximum value of the modulation signal margin, and then the third apparent power is obtained. In this way, the third apparent power is obtained by maximizing the modulation signal margin to fit the operating power of the MMC. It may be determined as the maximum value of MMC in the power range of stable operation. In this way, the overload operation boundary of grid-structured MMC may be clearly constructed, the overload capacity of MMC may be accurately defined, and the response ability of the power system to sudden faults may be enhanced. It is helpful to reasonably set the load level of MMC in the design and operation process, ensure its operation under safe and efficient conditions, and enhance the response ability of the power system to sudden faults. When the power grid fails or the demand changes sharply, the operation state of MMC may be quickly adjusted according to the overload operation boundary, so as to adapt to the new operating conditions, avoid apparatus damage or system failure caused by overload, ensure the safe and stable operation of power system, and improve the reliability and stability of the system.

The present disclosure also provides a computer-readable storage medium, which stores a computer program that may be used to perform the steps of the method for determining the MMC overload boundary provided in FIG. 1 above.

The present disclosure also provides a computer apparatus. At the hardware level, the computer apparatus includes a processor, an internal bus, a network interface, a memory, and a non-volatile memory. Of course, it may also include hardware required for other services. The processor reads the corresponding computer program from non-volatile memory into memory and then runs it to implement the steps of the method for determining the MMC overload boundary provided in FIG. 1 above.

Technicians in this field should understand that the embodiment of the present disclosure may be provided as a method, system, or computer program product. Therefore, the present disclosure may be in the form of a complete hardware embodiment, a complete software embodiment, or a combined embodiment of software and hardware. Moreover, the present disclosure may be used in the form of a computer program product implemented on one or more computer-available storage media (including but not limited to disk storage, CD-ROM, optical storage, etc.) containing computer available program code.

The present disclosure is described by referring to the flow chart and/or block diagram of the method, apparatus (system), and computer program product of the embodiment of the present disclosure. It should be understood that each process and/or box in the flow chart and/or block diagram may be implemented by computer program instructions, as well as the combination of processes and/or boxes in the flow chart and/or block diagram. These computer program instructions may be provided to general-purpose computers, special-purpose computers, embedded processors, or processors of other programmable data processing devices to generate a machine, so that instructions executed by processors of computers or other programmable data processing devices are used to generated a device that implements the functions specified in a flow chart, a process or multiple processes, and/or a block diagram, a box or multiple boxes.

These computer program instructions can also be stored in a computer-readable memory that can guide a computer or other programmable data processing apparatus to work in a specific way, so that the instructions stored in the computer-readable memory produce a manufactured product including an instruction apparatus, which implements a function specified in a flow chart or multiple processes and/or a block diagram or multiple boxes.

These computer program instructions can also be loaded onto a computer or other programmable data processing device, so that a series of operation steps are performed on the computer or other programmable device to generate computer-implemented processing, so that the instructions executed on the computer or other programmable device provide the steps for implementing the functions specified in a flow chart or multiple processes and/or a block diagram or multiple blocks.

It should be pointed out that the above specific implementation method can enable technicians in this field to understand the present disclosure more comprehensively, but does not limit the present disclosure in any way. Therefore, although the specification of the present disclosure has been described in detail, but the technical personnel in the field should understand that the present disclosure can still be modified or equivalent replacement; all technical solutions and improvements that are not separated from the spirit and scope of the present disclosure are covered in the scope of protection of the present disclosure patent. Any accompanying mark in the claim should not be regarded as a claim involved in the restriction.

What is claimed is:

1. A method for determining an overload boundary of MMC, comprising:
obtaining a power factor angle of a target MMC, and setting constraint ranges of an amplitude and a phase angle of a zero-sequence signal;
initializing two different working conditions of the target MMC, determining a maximum modulation signal margin of the two different working conditions under a condition of zero-sequence signal injection by the power factor angle,and an apparent power corresponding to the two working conditions and a constraint range of the amplitude and phase angle of the zero-sequence signal; wherein the two different working conditions are the working condition corresponding to a first apparent power and the working condition corresponding to a second apparent power;
based on the two different working conditions and the corresponding maximum modulation signal margin under the condition of zero-sequence signal injection, obtaining a third apparent power by a secant iteration method; and, when the modulation signal margin corresponding to the third apparent power is within a preset error range, determining the third apparent power as a maximum operating power of the target MMC at a current power factor angle;
obtaining a maximum operating power curve of the target MMC under different power factor angles by adjusting the power factor angle, wherein the maximum operating power curve is a limit boundary of an overload operation of the target MMC;
determining a maximum modulation signal margin of the two different working conditions under a condition of zero-sequence signal injection by the power factor angle, an apparent power corresponding to the two working conditions, and a constraint range of the amplitude and phase angle of the zero-sequence signal, by:
constructing a correlation between the amplitude and phase angle of the power factor angle, apparent power, and zero-sequence signal in the target MMC and the modulation signal margin;
wherein, by adjusting the amplitude and phase angle of the zero-sequence signal within the constraint range, the zero-sequence signal that maximizes the modulation signal margin is determined to be an optimal zero-sequence signal; and,
according to the initialized first apparent power and the second apparent power, obtaining the maximum modulation signal margin at the current power factor angle by the optimal zero-sequence signal.

2. The method for determining the overload boundary of MMC according to claim 1, wherein the method further comprises:
after initializing the two different working conditions of the target MMC, determining the maximum modulation signal margin of the two different working conditions without a zero-sequence signal by the power factor angle and the apparent power corresponding to the two working conditions;
based on the maximum modulation signal margin of the two different working conditions and their corresponding zero-sequence signal-free conditions, obtaining a fourth apparent power by an iteration of the secant method; and, when the modulation signal margin corresponding to the fourth apparent power is within the preset error range, determining the fourth apparent power as a starting operating power of the target MMC at the current power factor angle;
wherein, by adjusting the power factor angle, the starting power curve of the target MMC under different power factor angles is obtained, wherein the starting power curve is a starting boundary of the overload operation of the target MMC.

3. The method for determining the overload boundary of MMC according to claim 1, wherein the iterative formula of the secant method is:
$${S}_{n + 2} = {S}_{n + 1} - \frac{{M}_{gin} ( {S}_{n + 1} )}{{M}_{gin} ( {S}_{n + 1} ) - {M}_{gin} ( {S}_{n} )} ( {S}_{n + 1} - {S}_{n} ) ;$$
where Sₙ₊₂ is the third apparent power or the fourth apparent power, Sₙ and Sₙ₊₁ are the first apparent power and the second apparent power, respectively; M_{gin}(Sₙ) and M_{gin}(Sₙ₊₁) are the maximum modulation signal margins corresponding to the first apparent power and the second apparent power, respectively.

4. The method for determining the overload boundary of MMC according to claim 3, wherein the method further comprises:
under the condition that the modulation signal margin corresponding to the third apparent power or the fourth apparent power is not in the preset range, iterating the first apparent power and the second apparent power of the target MMC by the secant method until the modulation signal margin is within the preset error range.

5. The method for determining the overload boundary of MMC according to claim 1, wherein the constraint range expression of the amplitude and phase angle of the zero-sequence signal is:
$$\{ \begin{matrix}0 \leq {A}_{3} \leq 0.5 \\ 0 \leq {α}_{3} \leq 2 π\end{matrix} ;$$
a definition of the modulation signal margin M_{gin} of the target MMC is:
$${M}_{gin} = \frac{1 - {m}_{rect}}{2} ;$$
where A₃ is an amplitude of the zero-sequence signal, as is a phase angle corresponding to A₃, and m_{rect} is a correction value of the modulation signal, which is obtained by the power factor angle and the apparent power.

6. A device for determining an overload boundary, wherein the device comprises:
an acquisition module, configured to obtain a power factor angle of a target MMC, and constraint ranges of a zero-sequence signal amplitude and phase angle are set based on a physical limitation of the target MMC;
a calculation module, configured to initialize two different working conditions of the target MMC, wherein the maximum modulation signal margin of the two different working conditions under the condition of zero-sequence signal injection is determined by the power factor angle, the apparent power corresponding to the two working conditions and the constraint range of the amplitude and phase angle of the zero-sequence signal; and wherein the two different working conditions are the working condition corresponding to the first apparent power and the working condition corresponding to the second apparent power;
an iterative module, configured to obtain a third apparent power based on the two different working conditions and the corresponding maximum modulation signal margin in the case of zero-sequence signal injection; wherein when a modulation signal margin corresponding to the third apparent power is within a preset error range, the third apparent power is determined as a maximum apparent power of the target MMC to inject the optimal zero-sequence signal at the current power factor angle;
a determination module, configured to adjust the power factor angle, wherein a maximum apparent power curve of the optimal zero-sequence signal injected into the target MMC at different power factor angles is obtained, which is the limit boundary of the overload operation of the target MMC;
a calculation module configured to construct a correlation between the amplitude and phase angles of the power factor angle, the apparent power and the zero sequence signal in the target MMC and the modulation signal margin; wherein, by adjusting the amplitude and phase angle of the zero-sequence signal within the constraint range, the zero-sequence signal that maximizes the modulation signal margin is determined to be the optimal zero-sequence signal; and wherein, according to the initialized first apparent power and the second apparent power, the maximum modulation signal margin at the current power factor angle is obtained by the optimal zero-sequence signal.

7. A computer-readable storage medium, wherein the storage medium stores a computer program; when the computer program is executed by the processor, the method according to claim 1 is realized.

8. A computer apparatus, comprising a memory, a processor, and a computer program stored on the memory and running on the processor, wherein, when the program is executed by the processor, the method according to claim 1 is realized.
